(19) United States
(12) Patent Application Publication
(10) Pub. No.: US 2008/0123284 A1
(43) Pub. Date: May 29, 2008

(54) SERVER RACK DOOR MOUNTED DISPLAY ASSEMBLY

(75) Inventors: Joel J. Jaramillo, Round Rock, TX (US); Timothy C. Dearborn, Lakeway, TX (US)

Correspondence Address: LARSON NEWMAN ABEL POLANSKY & WHITE, LLP, 5914 WEST COURTYARD DRIVE, SUITE 200, AUSTIN, TX, 78730, US

(73) Assignee: DELL PRODUCTS, LP, Round Rock, TX (US)

(21) Appl. No.: 11/564,324

(22) Filed: Nov. 29, 2006

(51) Int. Cl. H05K 5/02

(52) U.S. Cl. 361/686; 361/681

(57) ABSTRACT

A server rack system includes a server rack, a server, a door, and a sub-panel. The server can be generally located within the server rack, and a door is mounted on the front of the server rack. Also, the door is constructed with an opening inside it, and has a sub-panel generally mounted within the opening. Additionally, the sub-panel rotates between a first position and a second position relative to the door with a display device mounted on the sub-panel. Further, the display device is configured to communicate with the server.

### FIELD OF THE DISCLOSURE

This disclosure relates generally to information handling systems, and relates more particularly to a display assembly mounted in the door of a server rack.

### BACKGROUND

As the value and use of information continues to increase, individuals and businesses seek additional ways to process and store information. One option available to users is information handling systems. An information handling system generally processes, compiles, stores, and/or communicates information or data for business, personal, or other purposes thereby allowing users to take advantage of the value of the information. Because technology and information handling needs and requirements vary between different users or applications, information handling systems may also vary regarding what information is handled, how the information is handled, how much information is processed, stored, or communicated, and how quickly and efficiently the information may be processed, stored, or communicated. The variations in information handling systems allow for information handling systems to be general or configured for a specific user or specific use such as financial transaction processing, airline reservations, enterprise data storage, or global communications. In addition, information handling systems may include a variety of hardware and software components that may be configured to process, store, and communicate information and may include one or more computer systems, data storage systems, and networking systems.

In many environments information handling systems are stored in racks. For instance, in data center environments racks (including racks compliant with standard EIA-310) are used to house multiple servers and other information handling system components. Racks are typically divided into multiple vertical sections, also referred to as “U's.” Components are then typically designed to fit within a vertical envelope corresponding to a number of U's. For instance, a 2U server is designed to fit within a 2U vertical space. In order to allow a user to interact with the rack mounted information handling system, many information handling systems provide a keyboard-display component mounted within the rack.

Some current keyboard-display components (which may also be referred to as a Keyboard Monitor Mouse (KMM)) include a display stored in a horizontal position, in a common horizontal plane with the keyboard and positioned behind the keyboard. Accordingly, a user must fully extend the keyboard-display component from the rack and then reach behind the display to pull the display up to a viewing position. This can be cumbersome work for shorter users who have a limited reach. Also, the monitor viewing angle may be limited by the vertical position of the keyboard-display component within the rack.

In existing keyboard-display components the display typically includes a screen such as an LCD screen. When the unit is stored within a storage position behind the keyboard, the LCD screen is typically facing upward. The upward facing LCD is then at risk of being damaged by components or other objects falling onto the LCD screen.

In some instances, depending upon the vertical placement of the keyboard-display within the rack the viewing angle of the display for users of different heights is not optimal and the distance between the keyboard and the display is often not optimized from a usability and viewability standpoint. Other available keyboard-display devices incorporate a so-called “clam shell” design with the display component folded over the keyboard during storage.

### BRIEF DESCRIPTION OF THE DRAWINGS

It will be appreciated that for simplicity and clarity of illustration, elements illustrated in the Figures have not necessarily been drawn to scale. For example, the dimensions of some of the elements are exaggerated relative to other elements. Embodiments incorporating teachings of the present disclosure are shown and described with respect to the drawings presented herein, in which:

FIG. 1 is a perspective view of an exemplary server rack with a Keyboard-Monitor-Mouse (KMM) unit in a closed outwardly facing position;

FIG. 2 is a perspective view of tie server rack with the KMM in an opened outwardly facing position;

FIG. 3 is a perspective view of the server rack with the KMM in an intermediate position;

FIG. 4 is a perspective view of the server rack with the KMM in an opened inwardly facing position;

FIG. 5 is a perspective view of a door or the server rack with the KMM in a closed outwardly facing position;

FIG. 6 is a perspective view of the door with the KMM in an intermediate position;

FIG. 7 is a perspective view of one side of the KMM;

FIG. 8 is a perspective view of another side of the KMM;

FIG. 9 is a schematic view of a system with multiple servers connected to the KMM using a keyboard, video, mouse (KVM) switch; and

FIG. 10 is a flow diagram of a method for accessing a server using a door-mounted KMM.

The use of the same reference symbols in different drawings indicates similar or identical items.

### DETAILED DESCRIPTION

The following description in combination with the Figures is provided to assist in understanding the teachings disclosed herein. The following discussion will focus on specific implementations and embodiments of the teachings. This focus is provided to assist in describing the teachings and should not be interpreted as a limitation on the scope or applicability of the teachings.

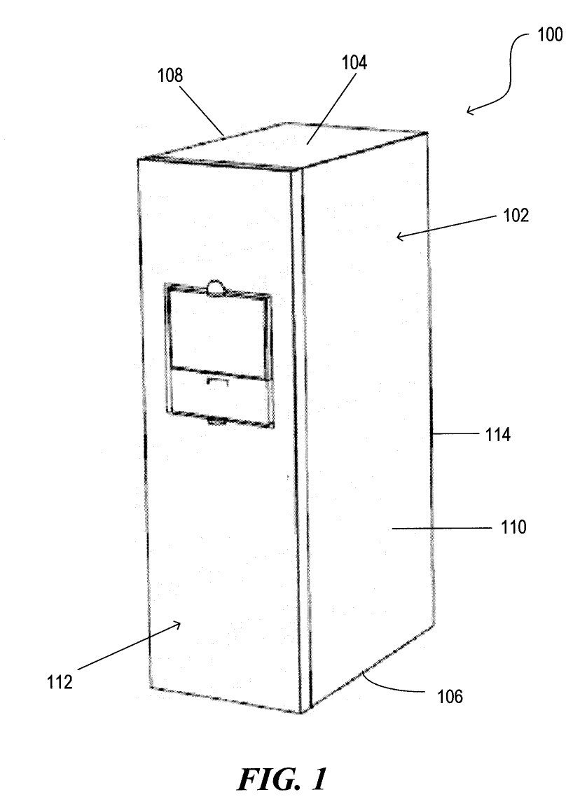

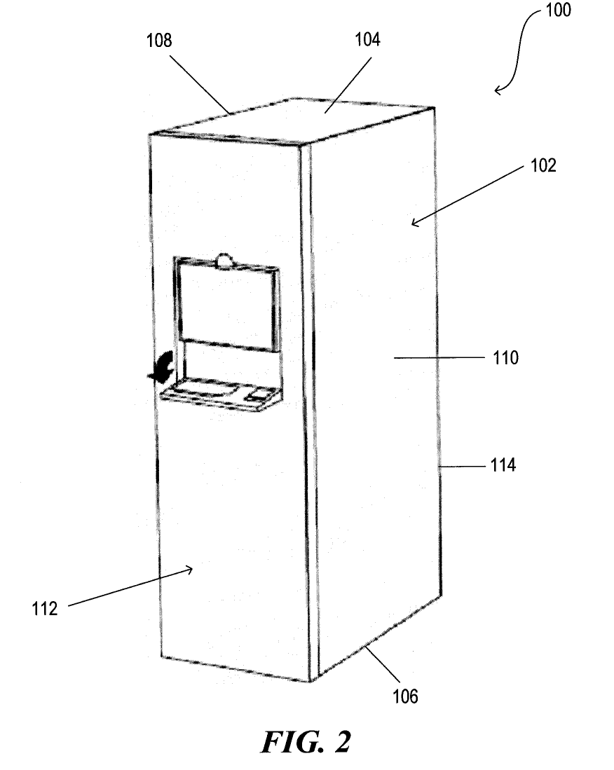

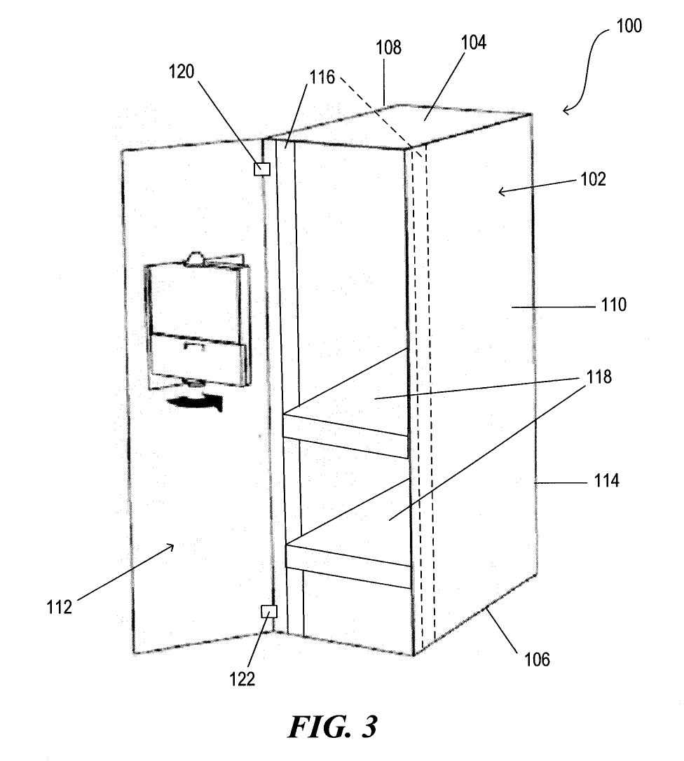

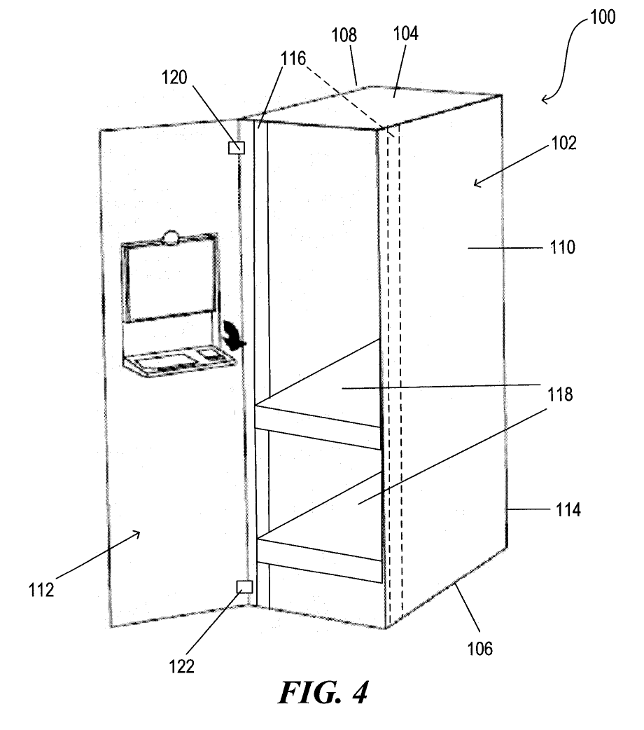

FIGS. 1 through 4 show a server rack system 1 00 for an information handling system. For purposes of this disclosure, an information handling system may include any instrumentality or aggregate of instrumentalities operable to compute, classify, process, transmit, receive, retrieve, originate, switch, store, display, manifest, detect, record, reproduce, handle, or utilize any form of information, intelligence, or data for business, scientific, control, entertainment, or other purposes. For example, an information handling system may be a personal computer, a PDA, a consumer electronic device, a network server or storage device, a switch router or other network communication device, or any other suitable device and may vary in size, shape, performance, functionality, and price. The information handling system may include memory, one or more processing resources such as a central processing unit (CPU) or hardware or software control logic. Additional components of the information handling system may include one or more storage devices, one or more communications ports for communicating with external devices as well as various input and output (I/O) devices, such as a keyboard, a mouse, and a video display. The information handling system may also include one or more buses operable to transmit communications between the various hardware components.

The server rack system 100 includes a server rack chassis 102 having a top surface 104, a bottom surface 106, a left surface 108, a right surface 110, a door 112, and a back surface 114. Inside the server rack chassis 102 there are a pair of rails 116 for the receiving and installation servers 118. The door 112 may connect to the left surface 108 of the server rack chassis 102 by hinges 120 and 122 to allow the door to swing open and closed in relation to the server rack chassis.

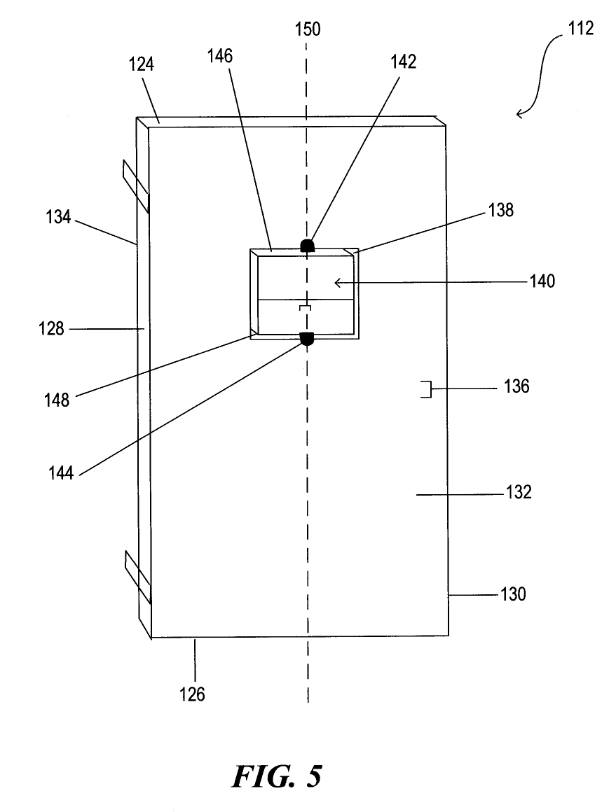

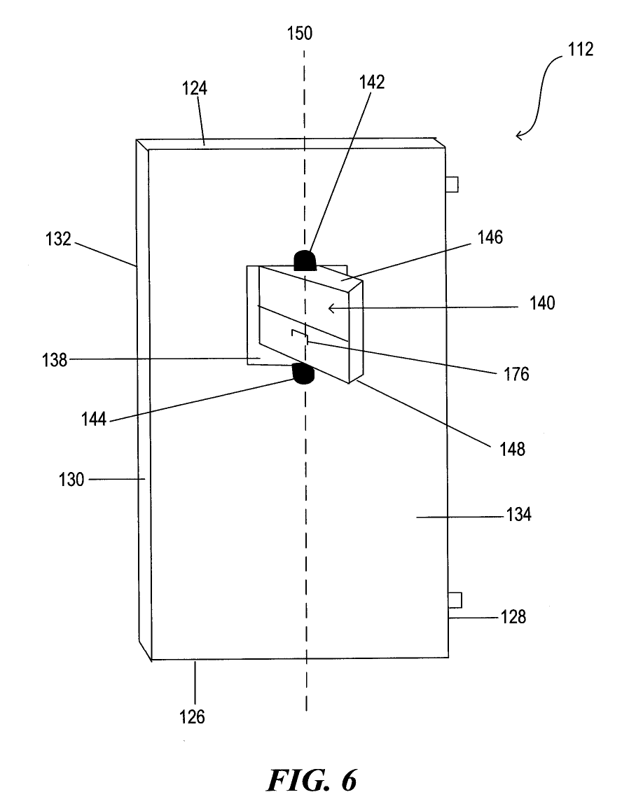

FIGS. 5 and 6 show an embodiment of the door 112 with a main panel top 124, a main panel bottom 126, a main panel left side 128, a main panel right side 130, a main panel front 132, and a main panel back 134. The main panel front 132 is equipped with a handle 136 to allow access to the inside of the server rack chassis 102 for maintenance or replacement of the servers 118. Further the door 112 has an opening 138 to allow the installment of a sub-panel 140. The sub-panel 140 is attached to the door 112 inside the opening 138 by connectors 142 and 144. In a preferred embodiment the connectors 142 and 144 are respectively attached to the center of a top 146 and a bottom 148 of the sub-panel 140. The connectors 142 and 144 also attach inside the opening 138 of the door 112, thereby allowing the sub-panel 140 to rotate between two positions relative to the door 112. The sub-panel 140 rotates along a central vertical axis 150 of the door 112 and the sub-panel 140. In one embodiment the sub-panel 140 may rotate between a generally outwardly facing position and a generally inwardly facing position relative to the door 112.

In an exemplary embodiment the connectors 142 and 144 may be cylindrical in shape, such that they might pivot and allow the sub-panel 140 to freely rotate 180 degrees around the central vertical axis 150. In one embodiment the sub-panel 140 may rotate from the generally outwardly facing position counter-clockwise (looking down onto the top 146 of the sub-panel 140) to the generally inwardly facing position. In this embodiment an operator may push the right side of the sub-panel 140 inward toward the inside of the server rack chassis 102 and the door 112, and rotate the sub-panel 180 degrees until the sub-panel is in the generally inwardly facing position. Once the sub-panel 140 has rotated 180 degrees in this direction it is possible for an operator to use the sub-panel. In another embodiment the sub-panel 140 may rotate from the generally outwardly facing position clockwise (looking down onto the top 146 of the sub-panel 140) to the generally inwardly facing position. In this embodiment an operator may push the left side of the sub-panel 140 inward toward the inside of the server rack chassis 102 and the door 112, and rotate the sub-panel 180 degrees until the sub-panel is in the generally inwardly facing position. Once the sub-panel 140 has rotated 180 degrees in this direction it is possible for an operator to use the sub-panel.

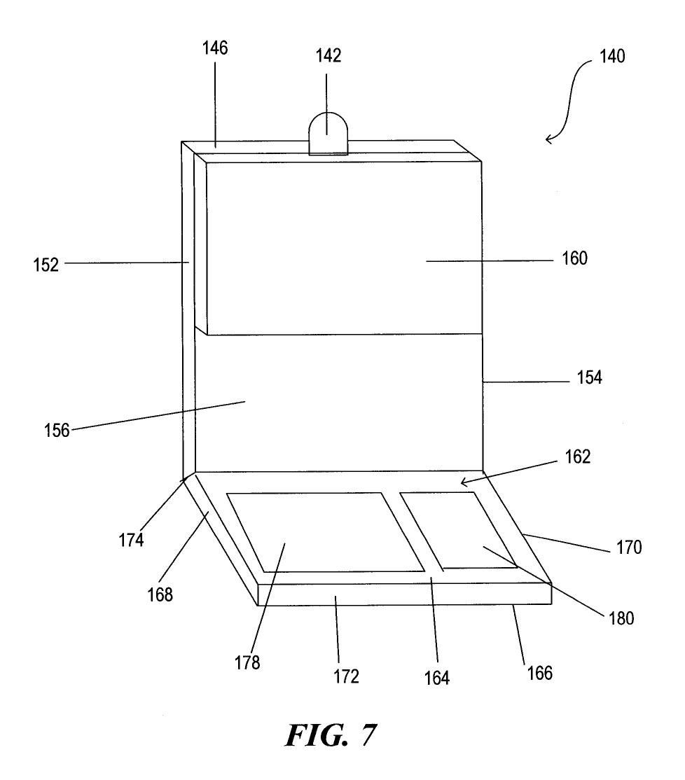

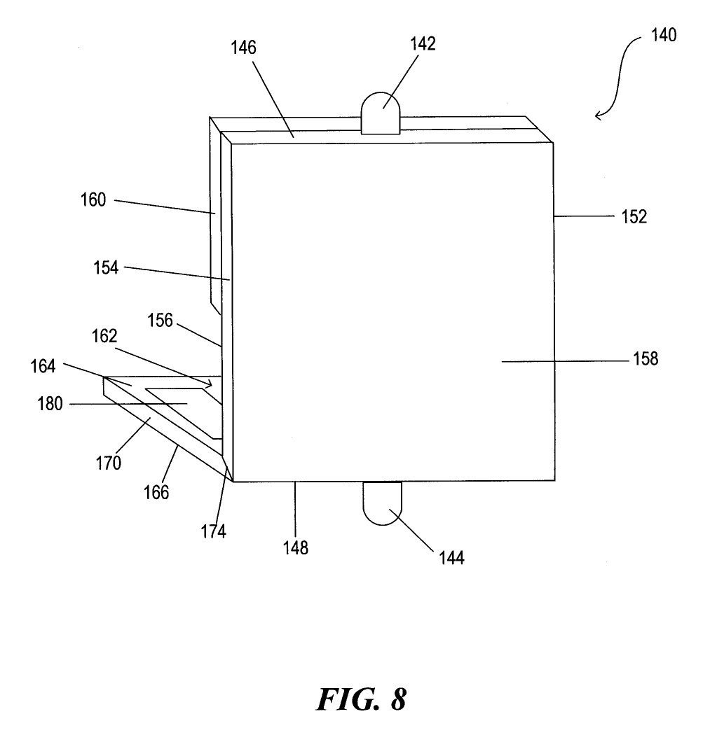

FIGS. 7 and 8 show one particular embodiment of the sub-panel 140 with the top 146, the bottom 148, a left side 152, a right side 154, a front 156, and a back 158. The sub-panel 140 is configured to receive a display device 160 and a folding tray 162. Some possible examples of the display device are a Liquid Crystal Display (LCD), a plasma display, and a Light Emitting Diode (LED) display. The tray 162 has a top 164, a bottom 166, a left side 168, a right side 170, a front 172, and a back 174. A handle 176 (see FIG. 6) is mounted on the back 174 to allow an operator to fold down the tray 162. Mounted on the top 164 of tray 162 are two input devices, a keyboard 178 and a pointing device 180, used for controlling at least one server 118. Depending on the embodiment used the pointing device 180 may be a mouse, a track ball, or a track pad. In an embodiment the connectors 142 and 144 allow power cables to the display device 160. In another possible embodiment the connectors 142 and 144 allow connecting cables to connect the display device 160, the keyboard 178, and the pointing device 180 with each other and the rest of the server rack system 100. In an exemplary embodiment the keyboard 178 has Universal Serial Bus (USB) ports so that it can be accessed as a crash cart for reading and writing files.

In one embodiment the sub-panel 140, the display device 160, the keyboard 178, and the pointing device 180 can be used when the door 112 is closed, by folding down the tray 162 when the sub-panel 140 is in an outwardly facing position. When the door 112 is open the sub panel can be rotated 180 degrees to an inwardly facing position, which allows access to the sub-panel 140, the display device 160, the keyboard 178, and the pointing device 180. In either the inwardly facing position or the outwardly facing position the display device 160 can give the status of the sever rack system 100. In one embodiment the sub-panel 140 and the display device 160 are in the inwardly facing position and allow the user to work on any of the systems in the rack.

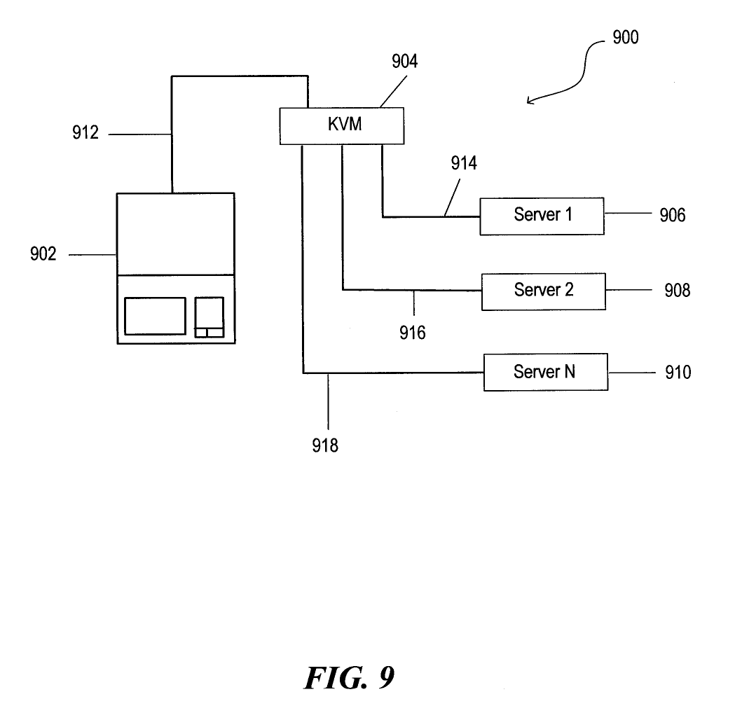

FIG. 9 shows a block diagram of an exemplary embodiment of a system 900 comprising a keyboard monitor mouse (KMM) 902, a keyboard, video, mouse (KVM) switch 904, a first server 906, a second server 908, and an nth server 910. The KMM 902 communicates with the KVM switch 904 through a connection 912. The first server 906 communicates with the KVM switch 904 through a connection 914. The second server 908 communicates with the KVM switch 904 through a connection 916. The nth server 910 communicates with the KVM switch 904 through a connection 918. In one possible embodiment the connections 912, 914, 916, and 918 are wired connections. In another possible embodiment the connections 912, 914, 916, and 918 are wireless connections. In the exemplary embodiment, the KVM switch 904 allows, by selecting one of the first server 906, the second server 908, or the nth server 910, the KMM 902 to communicate with each of the servers 906, 908, 910 individually without re-cabling.

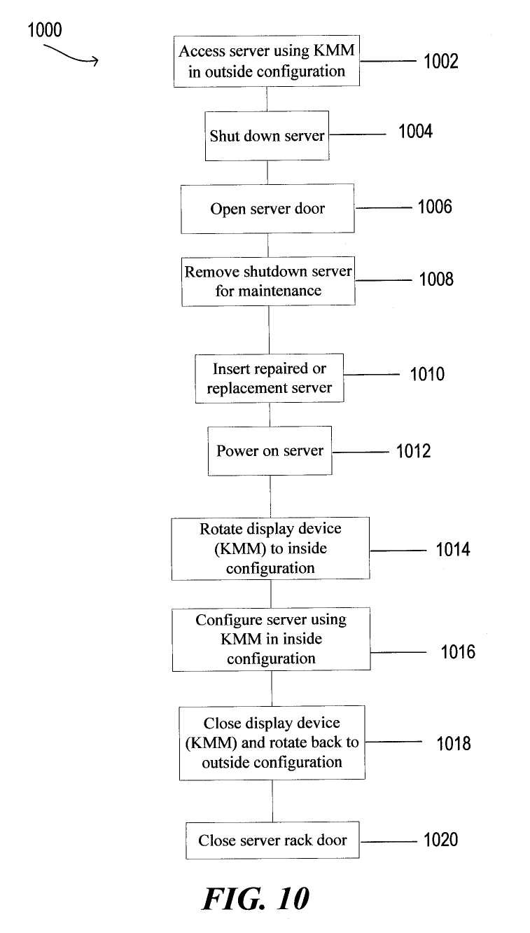

FIG. 10 shows a flow diagram 1000 illustrating an exemplary method of accessing a server using a door mountable keyboard monitor mouse (KMM). A server may be a remote memory, a hard drive, and processor that multiple computers could use to save or access from a central location. The monitor in a KMM may include: a Liquid Crystal Display (LCD), a plasma display, or a Light Emitting Diode (LED) display. The mouse in a KMM may include: a mouse, a track ball, or a track pad. In an exemplary embodiment, the server is accessed using the KMM in an outside configuration as shown at 1002. Access to the server may be gained by logging into the server The server may be shut down, as illustrated at 1004. By using the KMM the server may be shut down. The door to the server rack may be opened, as shown at 1006. As shown at 1008, the server may be removed for maintenance. This may be accomplished by completely removing the server from the rack or by moving the server into a position that allows access to the components. A new or repaired server may be inserted into the server rack, as illustrated at 1010. The server may be turned on, as illustrated at 1012. The KMM may be rotated to an inside configuration, as illustrated at 1014. The keyboard and mouse component of the KMM may need to be moved to a close position to allow the KMM to rotate to the inside configuration. As illustrated at 1016, the server may be configured using the KMM in the inside configuration. Configuring the server may involve monitoring the start up procedure on the monitor. Configuring the server may also involve responding to instructions presented on the monitor. As illustrated at 1018, the KMM may be closed and rotated back to the outside configuration. This may involve logging out of the server, This may also involve moving the keyboard mouse component to a closed position to allow the KMM to rotate to the outside configuration. The door to the server rack may be closed, as illustrated at 1020. The KMM may be used to continue to monitor the server status while the door is closed and the KMM is in the outside configuration. Monitoring the server may involve using the KMM to look at the functions and actions that the server might be doing at any given time or over a certain period of time to ensure that the server is working properly.

Although only a few exemplary embodiments have been described in detail above, those skilled in the art will readily appreciate that many modifications are possible in the exemplary embodiments without materially departing from the novel teachings and advantages of the embodiments of the present disclosure. Accordingly, all such modifications are intended to be included within the scope of the embodiments of the present disclosure as defined in the following claims. In the claims, means-plus-function clauses are intended to cover the structures described herein as performing the recited function and not only structural equivalents, but also equivalent structures.

What is claimed is:

1. A door comprising:
a main panel having an opening;
a sub-panel generally mounted within the opening of the main panel, the sub-panel being rotatable between a first position and a second position relative to the main panel; and
a display device mounted on the sub-panel.

2. The door of claim 1 wherein the first position of the sub-panel is generally outwardly facing relative to the main panel, the second position of the sub-panel is generally inwardly facing relative to the main panel, and the sub-panel rotates around a vertical axis.

3. The door of claim 2 wherein the vertical axis is a central vertical axis relative to the sub-panel.

4. The door of claim 1 wherein the display device is one of a Liquid Crystal Display (LCD), a plasma display, and a Light Emitting Diode (LED) display.

5. The door of claim 1 wherein the display device displays the status of a server rack system.

6. The door of claim 1wherein the sub-panel is configured to receive at least one of a keyboard, a mouse, a track ball, a track pad and any combination thereof.

7. The door of claim 1 wherein the door is configured to attach to a server rack.

8. A server rack comprising;
a frame;
a door mounted on the frame, the door constructed with an opening;
a sub-panel generally mounted within the opening, the sub-panel being rotatable between a first position and a second position relative to the main panel; and
a display device mounted on the sub-panel.

9. The server rack of claim 8 wherein the first position of the sub-panel is generally outwardly facing relative to the door, the second position of the sub-panel is generally inwardly facing relative to the door, and the sub-panel rotates around a vertical axis.

10. The server rack of claim 9 wherein the vertical axis is a central vertical axis relative to the sub-panel.

11. The server rack of claim 8 wherein the display device is one of a Liquid Crystal Display (LCD), a plasma display, and a Light Emitting Diode (LED) display.

12. The server rack of claim 8 wherein the display device displays the status of a server rack system.

13. The server rack of claim 8 wherein the sub-panel is configured to receive at least one of a keyboard, a mouse, a track ball, a track pad and any combination thereof.

14. A system comprising:
a server rack;
a server generally located within the server rack;
a door mounted on the server rack, the door constructed with an opening;
a sub-panel generally mounted within the opening, the sub-panel being rotatable between a first position and a second position relative to the door; and
a display device mounted on the sub-panel, the display device configured to communicate with the server.

15. The system of claim 14 wherein the first position of the sub-panel is generally outwardly facing relative to the door, the second position of the sub-panel is generally inwardly facing relative to the door, and the sub-panel rotates around a vertical axis.

16. The system of claim 15 wherein the vertical axis is a central vertical axis relative to the sub-panel.

17. The system of claim 14 wherein the display device is one of a Liquid Crystal Display (LCD), a plasma display, and a Light Emitting Diode (LED) display.

18. The system of claim 14 wherein the display device displays the status of a server rack system.

19. The system of claim 14 wherein the sub-panel is configured to receive at least one of a keyboard, a mouse, a track ball, a track pad and any combination thereof.

20. The system of claim 18 wherein the input device is configured to communicate with the server.
